(19) United States
(12) Patent Application Publication
(10) Pub. No.: US 2005/0063506 A1
(43) Pub. Date: Mar. 24, 2005

(54) Method and system for jitter correction

(75) Inventor: Yong Zhang, Poway, CA (US)

Correspondence Address: ROGITZ & ASSOCIATES, Suite 3120, 750 B Street, San Diego, CA, 92101, US

(73) Assignees: SONY CORPORATION, Tokyo (JP); SONY ELECTRONICS INC., Park Ridge, NJ (US)

(21) Appl. No.: 10/668,468

(22) Filed: Sep. 23, 2003

(51) Int. Cl. H03D 3/24

(52) U.S. Cl. 375/376

(57) ABSTRACT

Jitter in parallel data streams is corrected for by generating one optimized clock of 2N correction clock pulses for each received clock pulse from a phase locked loop. Any one of the 2N correction clock pulses existing within a temporally overlapping region of the bits may be used to latch bit values in the streams.

### FIELD OF THE INVENTION

I. Field of the Invention

The present invention relates generally to parallel stream digital communications.

II. Background of the Invention

In digital communication, data typically is transmitted in parallel streams, e.g., in eight, sixteen, thirty two, sixty four, etc. parallel streams of data bits. The streams represent temporally linked bits, so that when the streams are received, bits from each stream are simultaneously processed together for display or use. As an example, a pixel color might be represented by eight bits, with the eight bits being received simultaneously in eight different bus lines and processed (by, e.g., a video monitor) to render the pixel on a display. As another example, MPEG2 data and auxiliary data signals from a digital demodulator can be passed to an MPEG decoder through parallel bus lines.

It will be appreciated that the streams must be temporally synchronized, so that related bits can be properly combined. Part of the synchronization process includes generating a clock signal, which essentially is a sequence of clock pulses. At the rising (or falling) edge of each pulse, a device in the receiver referred to as a bus latch samples each stream. This sampling is referred to as “latching” the value in each stream. The values (zeroes or ones) are then sent to a processor for further use.

As a practical matter, however, it is often the case that related bits in the streams do not arrive at the receiver's bus latch simultaneously. Instead, owing to delays in transmission that are attributable to differing lengths between the transmission paths carrying the streams, processing differences between logic gates through which the streams respectively pass, signal reflection, and other factors, the synchronization of the streams can deteriorate. This is known as “jitter”. The result is that when the streams are sampled at the rising edge of the clock pulse, the portion of a particular stream that is supposed to be latched along with corresponding portions in the other streams in fact might be earlier or later than expected, with the result that the bus latch might indicate the wrong value for the bit carried by the stream. The deterioration of the synchronization accumulates stage by stage such that a high data error rate ensues and decode processing fails. Having recognized this problem, the solution below is provided.

### SUMMARY OF THE INVENTION

A system for correcting jitter in data streams includes a correction clock module that receives a clock signal defining a clock pulse frequency. The correction clock module generates a correction clock signal which has a frequency higher than the clock pulse frequency. The correction clock module latches values of at least two bits in respective data streams using a correction clock pulse that is within an overlapping period defined by the bits.

In another aspect, a method for correcting jitter between data streams includes receiving a clock signal defining a clock pulse period, and using the clock signal, generating at least one optimized signal from plural correction clock pulses, with several choices possibly existing for the optimized signal and with the possible choices being temporally located within a single clock period. Using one of the optimized signals, usually the one in the middle of an overlap between bits experiencing jitter, values in plural data streams are latched.

In a preferred embodiment, the method includes generating at least 2N correction clock pulses for a single clock period, wherein N is an integer. In an illustrative embodiment, two data streams may have respective bits defining a temporally overlapping time period, and the method includes using at least one correction clock pulse in the overlapping time period to latch values in the streams. The original clock signal may be received from a phase locked loop and the correction clock pulses may be generated by a voltage controlled oscillator (VCO). If desired, the method may further include feeding back the output of the VCO through a divider to a phase detector receiving the clock signal. The correction clock pulse used for latching may be selected using a selector element and a demultiplexer.

In still another aspect, a jitter correction system includes means for generating plural correction clock pulses for each clock pulse of a clock signal, and means for correlating at least a first correction clock pulse with at least two data bits received in respective parallel data streams. Means are provided for identifying values of the data bits at least in part using the first correction clock pulse.

The details of the present invention, both as to its structure and operation, can best be understood in reference to the accompanying drawings, in which like reference numerals refer to like parts, and in which:

### BRIEF DESCRIPTION OF THE DRAWINGS

FIG. 1 is a block diagram showing the present system;

FIG. 2 is a block diagram of the digital time base correction module;

FIG. 3 is a series of schematic diagrams of bit streams entering and leaving a bus latch device; and

FIG. 4 is a flow chart of the overall logic.

### DETAILED DESCRIPTION OF THE PREFERRED EMBODIMENT

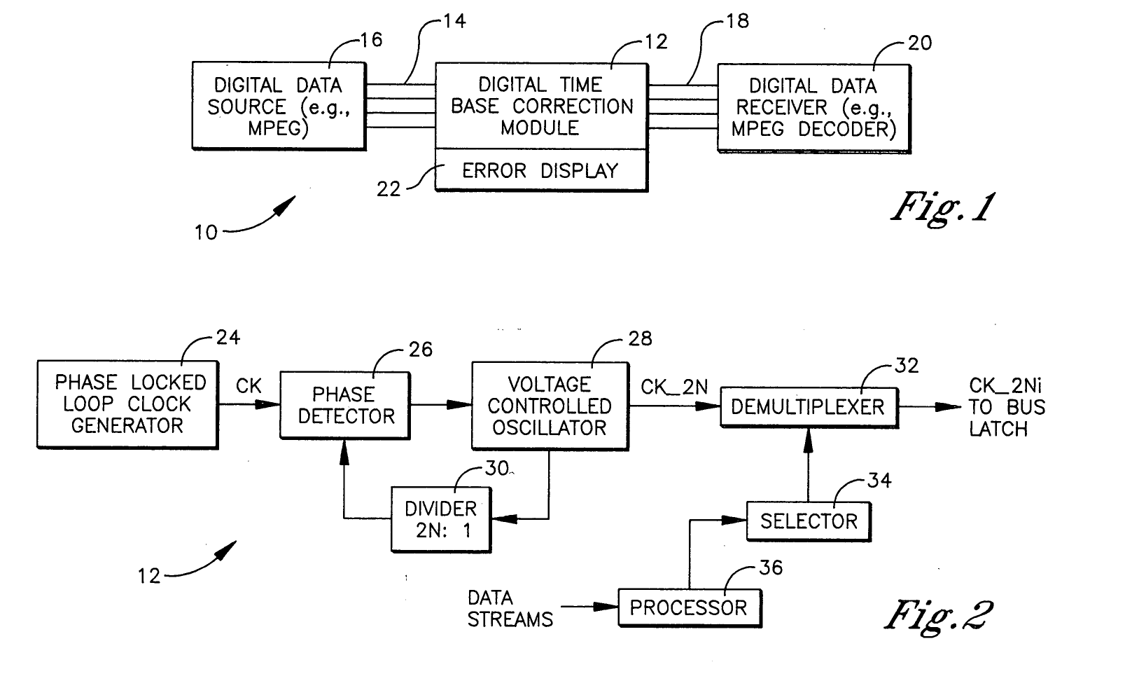

Referring initially to FIG. 1, a system is shown, generally designated 10, which includes a processor such as a programmable logic device (PLD) that establishes a digital time base correction module 12 for correcting for jitter between data streams 14 received from a source 16 of data, e.g., a multimedia source, so that jitter-free streams 18 can be displayed or otherwise used by a digital data receiver 20, such as an MPEG decoder of a multimedia display apparatus. The time error between the data streams 14 may be presented on a display 22 such as an LED error reader, logic analyzer, or MPEG decoder TV display.

FIG. 2 shows that the correction module 12 receives a clock signal from a source such as a phase locked loop clock signal generator 24. In one preferred non-limiting embodiment, the phase locked loop signal generator 24 may be an ICS570 analog/digital phase locked loop integrated circuit device. The clock signal is a series of temporally-spaced pulses. Each pulse defines a clock pulse period, and the signal defines a clock frequency the inverse of which is the clock period.

A phase detector 26 receives the clock signal to detect the phase thereof. The clock signal is then sent to a correction clock pulse generator, which in the preferred embodiment may be implemented by a voltage controlled oscillator (VCO) 28. The preferred correction clock pulse generator generates a correction clock signal that has 2N correction clock pulses for each clock pulse, wherein N is an integer such as, e.g., eight (8). In the particularly preferred embodiment, the correction clock signal may be thought of as being composed of two signals, one being the opposite phase of the other. The phase detector 26 may be used to establish the two oppositely-phased correction clock signals. In any case, the frequency of the correction clock signal is higher than (by, e.g., a multiple of 2N) the frequency of the clock signal from the PLL 24.

As shown in FIG. 2, if desired the output of the VCO 28 may be sent to a divider 30 that divides the output by 2N, with the output of the divider 30 being fed back to the phase detector 26 to enable the original clock frequency to be recovered, but at a 1/2N duty cycle.

A demultiplexer 32 receives the correction clock signal from the VCO 28 as shown. Based on input from a selector 34, the demultiplexer 32 obtains an i^{th} one of the 2N correction clock pulses (denoted CK_{—}2Ni in FIG. 2) and sends that correction clock pulse to a bus latch, described further below, which may use the leading edge of the correction clock pulse to latch values in the data streams.

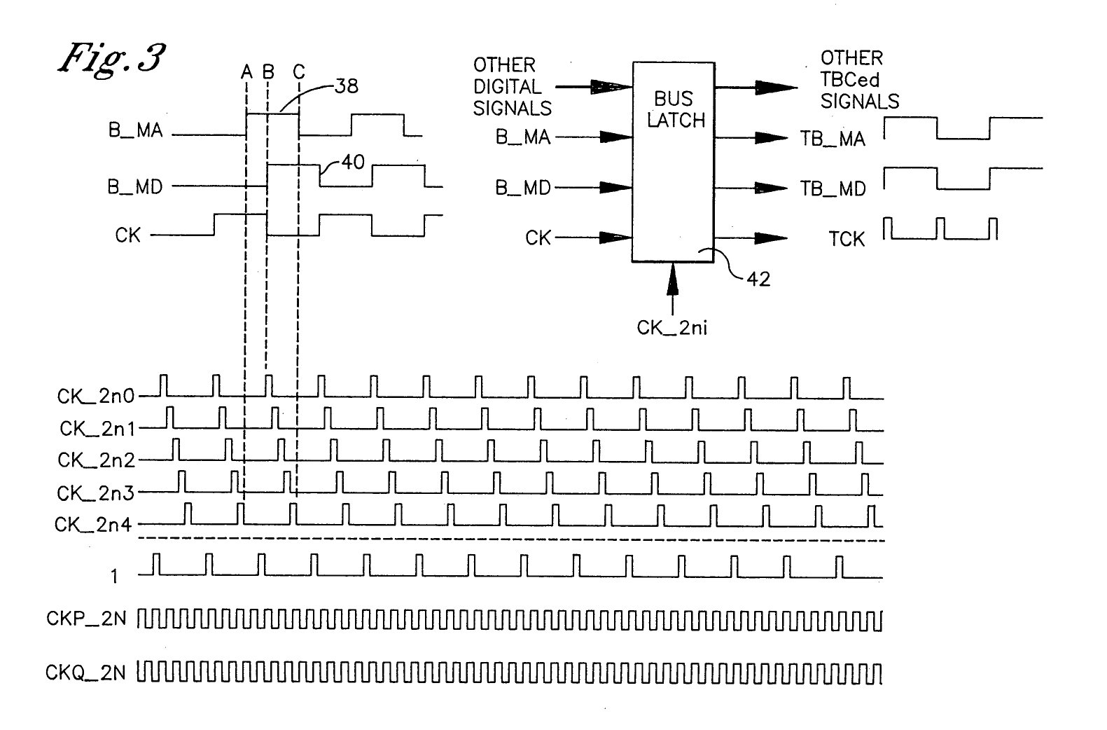

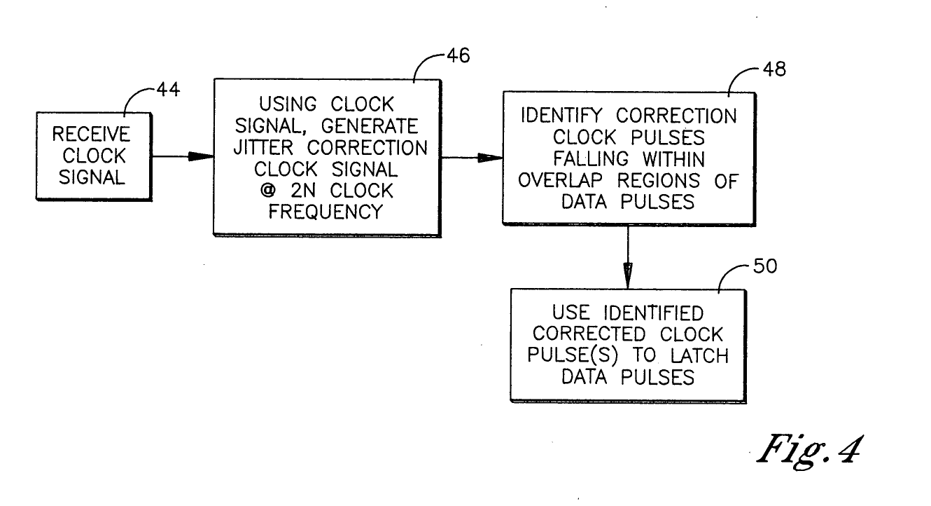

In one non-limiting embodiment, the selector 34 may be implemented by an external rotary binary coded decimal (BCD) switch that is controlled by a human looking at the graph of FIG. 3 as might be presented on, e.g., the display 22 of FIG. 1. The selector 34 may alternatively be controlled by a processing device 36 that accesses the data streams and that executes the logic shown further below in reference to FIGS. 3 and 4. As but one example, the VCO 28, demultiplexer 32, and selector 34 may be implemented within a programmable logic device such as a CPLD or FPGA integrated circuit (IC).

FIGS. 3 and 4 illustrate how the correction clock signal generated above is used to latch bit values in parallel streams that are affected by jitter. FIG. 3 shows two parallel data streams B_MA (representing the most advanced bit) and B_MD (representing the most delayed bit) of respective data bits 38, 40 that are supposed to be correlated with each other, but that are temporally displaced from each other because of jitter. FIG. 3 also shows the clock signal CK from the phase locked loop 24. It is to be understood that more data streams in addition to the streams B_MA and B_MD can be provided to a bus latch device 42, as indicated in FIG. 3.

In the example shown, time line A represents the leading edge of the data bit 38 of the data stream B_MA, timeline C represents its trailing edge, and timeline B represents the leading edge of the data bit 40 of the data stream B_MD. In this example, the trailing edge of the clock signal pulse CK also happens to be at timeline B, meaning that if the conventional clock CK signal from the phase locked loop is used to latch bit values, the value of the bit 40 will be latched at zero, instead of one as intended.

For this reason, the correction clock signal is used to latch bit values. In FIG. 3, the correction clock signal is broken down into its two constituent opposite-phased parts CKP_{—}2N and CKQ_{—}2N as shown. To illustrate the logic below for the reader, these correction clock signals are partially exploded to show correction clock pulses for CK_{—}2n0, CK_{—}2n-1, CK_{—}2n-2, CK_{—}2n-3, CK_{—}2N-4, . . . , CK_{—}1. In one non-limiting application, the first correction clock pulse CK_{—}2n0 may be programmed to start at the rising edge of the packet sync signal of a multimedia signal.

In the example shown in FIG. 3, the bits 38, 40 of the data streams B_MA and B_MD define a temporally overlapping region between the timelines B and C. As also illustrated, the correction clock pulses CK_{—}2n0, CK_{—}2n-1, CK_{—}2n-2, CK_{—}2n-3, and CK_{—}2N-4 are temporally within this overlap region and thus can be considered to be optimized signals for purposes of latching. Accordingly, a human observing the signals shown in FIG. 3 on, e.g., the display 22 in FIG. 1 can manipulate the selector 34 as appropriate to select an i^{th} one (CK_{—}2ni) of the correction clock pulses CK_{—}2n0, CK_{—}2n-1, CK_{—}2n-2, CK_{—}2n-3, and CK_{—}2N-4 for extraction by the demultiplexer 32 and input into the bus latch device 42, which uses, e.g., the leading edge of the CK_{—}2Ni correction clock pulse to latch the correct values of the bits 38, 40. The resulting time base-corrected data value signals TB_MA and TB_MD, in combination with an aligned version of the correction clock pulse (denoted “TCK”), are shown in FIG. 3. Usually, the correction clock pulse in the middle of the overlap region is selected. Once the desired correction clock pulse is known it need by the only one generated, if desired.

As mentioned above, the selection of the correction clock pulse CK_{—}2Ni to use as input to the bus latch device 42 may be done by a human, and it may also be programmatically accomplished by the processing device 36 using the above logic (implemented in hardware or software) and shown for convenience in flow chart format in FIG. 4. At block 44 the clock signal from the phase locked loop 24 is received, and then at block 46 the clock signal is used as described above to generate the correction clock signal at, e.g., 2N times the clock signal frequency. Moving to block 48, those correction clock pulses falling within the overlap period defined by the bits 38, 40 of the data streams are identified. One or more of the identified correction clock pulses is then used at block 50 by the bus latch device 42 to latch the values of the data bits 38, 40. In the example shown, the mid-most (relative to the overlap region between timelines B and C) correction clock pulse may be used.

While the particular METHOD AND SYSTEM FOR JITTER CORRECTION as herein shown and described in detail is fully capable of attaining the above-described objects of the invention, it is to be understood that it is the presently preferred embodiment of the present invention and is thus representative of the subject matter which is broadly contemplated by the present invention, that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather l“one or more”. It is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. §112, sixth paragraph, unless the element is expressly recited using the phrase “means for” or, in the case of a method claim, the element is recited as a “step” instead of an “act”. Absent express definitions herein, claim terms are to be given all ordinary and accustomed meanings that are not irreconcilable with the present specification and file history.

1. A method, comprising:
receiving a clock signal defining a clock pulse period;
using the clock signal, generating at least one correction clock pulse, the correction clock pulse being temporally within a single clock period; and
using at least one correction clock pulse, latching values in plural data streams.

2. The method of claim 1, comprising generating at least 2N correction clock pulses for a single clock period, wherein N is an integer.

3. The method of claim 1, wherein at least two data streams have respective bits defining a temporally overlapping time period, and the method includes using at least one correction clock pulse in the overlapping time period to latch values in the streams.

4. The method of claim 1, wherein the clock signal is received from a phase locked loop and the correction clock pulses are generated by a voltage controlled oscillator (VCO).

5. The method of claim 4, comprising feeding back an output of the VCO to a phase detector receiving the clock signal.

6. The method of claim 1, comprising selecting at least one correction clock pulse for the using act using at least one selector element and at least one demultiplexer.

7. A system for correcting jitter in data streams, comprising:
a correction clock module receiving a clock signal defining a clock pulse frequency and generating a correction clock signal having a frequency higher than the clock pulse frequency, the correction clock module latching values of at least two bits in respective data streams using at least one correction clock pulse within an overlapping period defined by the at least two bits.

8. The system of claim 7, wherein the correction clock module generates at least 2N correction clock pulses for a single clock signal period, wherein N is an integer.

9. The system of claim 7, wherein the clock signal is received from a phase locked loop and the correction clock pulses are generated by a voltage controlled oscillator (VCO).

11. The system of claim 9, wherein an output of the VCO is fed back to a phase detector receiving the clock signal.

12. The system of claim 11, comprising at least one selector element and at least one demultiplexer for selecting the correction clock pulse with which to latch bit values.

13. A jitter correction system comprising:
means for generating plural correction clock pulses for each clock pulse of a clock signal;
means for correlating at least a first correction clock pulse with at least two data bits received in respective parallel data streams; and
means for identifying values of the data bits at least in part using the first correction clock pulse.

14. The system of claim 13, wherein the means for generating includes at least one voltage controlled oscillator (VCO).

15. The system of claim 13, wherein the means for identifying includes at least one bus latch.

16. The system of claim 13, wherein the means for generating generates at least 2N correction clock pulses for a single clock period, wherein N is an integer.

17. The system of claim 13, wherein at least two data streams have respective bits defining a temporally overlapping time period, and the means for correlating correlates the first correction clock pulse by determining that the first correction clock pulse is in the overlapping time period.

18. The system of claim 14, comprising feeding back an output of the VCO to a phase detector receiving the clock signal.
